(19) United States
(12) Patent Application Publication
(10) Pub. No.: US 2004/0099375 A1
(43) Pub. Date: May 27, 2004

(54) Edge-contact ring for a wafer pedestal

(76) Inventors: Yanghua He, Richardson, TX (US); Chad J. Kaneshige, McKinney, TX (US); Michael S. Wang, Plano, TX (US)

Correspondence Address: TEXAS INSTRUMENTS INCORPORATED, P O BOX 655474, M/S 3999, DALLAS, TX, 75265

(21) Appl. No.: 10/301,464

(22) Filed: Nov. 21, 2002

(51) Int. Cl. C23F 1/00; H01L 21/306

(52) U.S. Cl. 156/345.23; 156/345.19

(57) ABSTRACT

An embodiment of the invention is an edge-contact ring 15 used to support a wafer 3 on a pedestal plate 16.

### BACKGROUND OF THE INVENTION

This invention relates to the use of an edge-contact ring to support a wafer on a pedestal.

### BRIEF DESCRIPTION OF THE DRAWINGS

FIG. 1 shows a portion of the wafer load/unload stage of the prior art wafer polisher.

FIG. 2 shows a top view of the prior art pedestal film.

FIG. 3 shows a pedestal film signature on a product wafer.

FIG. 4 shows the top view of pedestal film in accordance with one embodiment of the invention.

FIG. 5 shows the top view of pedestal film in accordance with another embodiment of the invention.

FIG. 6 shows the top view of an edge-contact ring in accordance with another embodiment of the invention.

FIG. 7 shows a portion of the wafer load/unload stage in accordance with the present invention.

FIGS. 8A-8F show alternative cross-section shapes for the edge-contact ring.

### DETAILED DESCRIPTION OF THE INVENTION

Minimizing or eliminating the contact between the wafer pedestal and the active dies of a wafer, through the use of an edge-contact ring, will improve the manufacturing yield. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details. In other instances, well-known structures or operations are not shown in detail to avoid obscuring the invention.

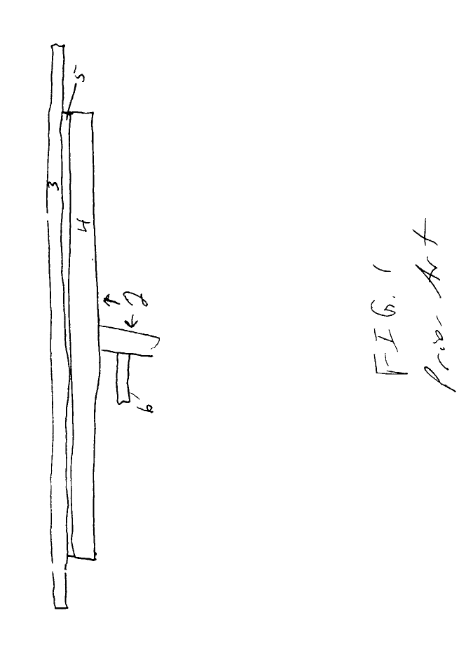

Referring to the drawings, FIG. 1 shows the relationship between a wafer pedestal 2 and an example 200 mm wafer 3. The wafer 3 is put on the wafer pedestal 2 in a face down position (i.e. the side of wafer 3 containing the active dies is facing toward the wafer pedestal 2). The pedestal 2 is located in the wafer load/unload stage of a 200 mm Chemical Mechanical Polishing (CMP) polisher manufactured by Applied Materials (i.e. sold under the model name ‘Mirra’). The top of the pedestal 2 is a plate-shaped surface (“plate”) 4 made generally of stainless steel. A piece of material (“film”) 5 is attached to plate 4.

During the CMP manufacturing process, a robotic arm (not shown) removes a wafer 3 from a holding area and moves the wafer 3 to the head-clean load/unload station of the CMP machine. The wafer 3 is first placed in the load/unload stage of the head-clean load/unload station on top of the wafer pedestal 2. When a wafer 3 is placed in the wafer load/unload stage the film 5 contacts the wafer 3 on the side of the wafer 3 that contains the active die (that are being created during the manufacturing process). Note that the wafer 3 has a larger circumference than the prior art plate 4.

There are various tubings 6 that bring deionized water or a vacuum to the plate 4. The deionized water shoots through various holes in the wafer side of plate 4—and the associated holes in the film 5—and is used to clean the carrier or the wafer 3. The vacuum also flows through the same tubings 6 and is used to hold the wafer 3 to the plate 4 of the wafer pedestal 2 when desired.

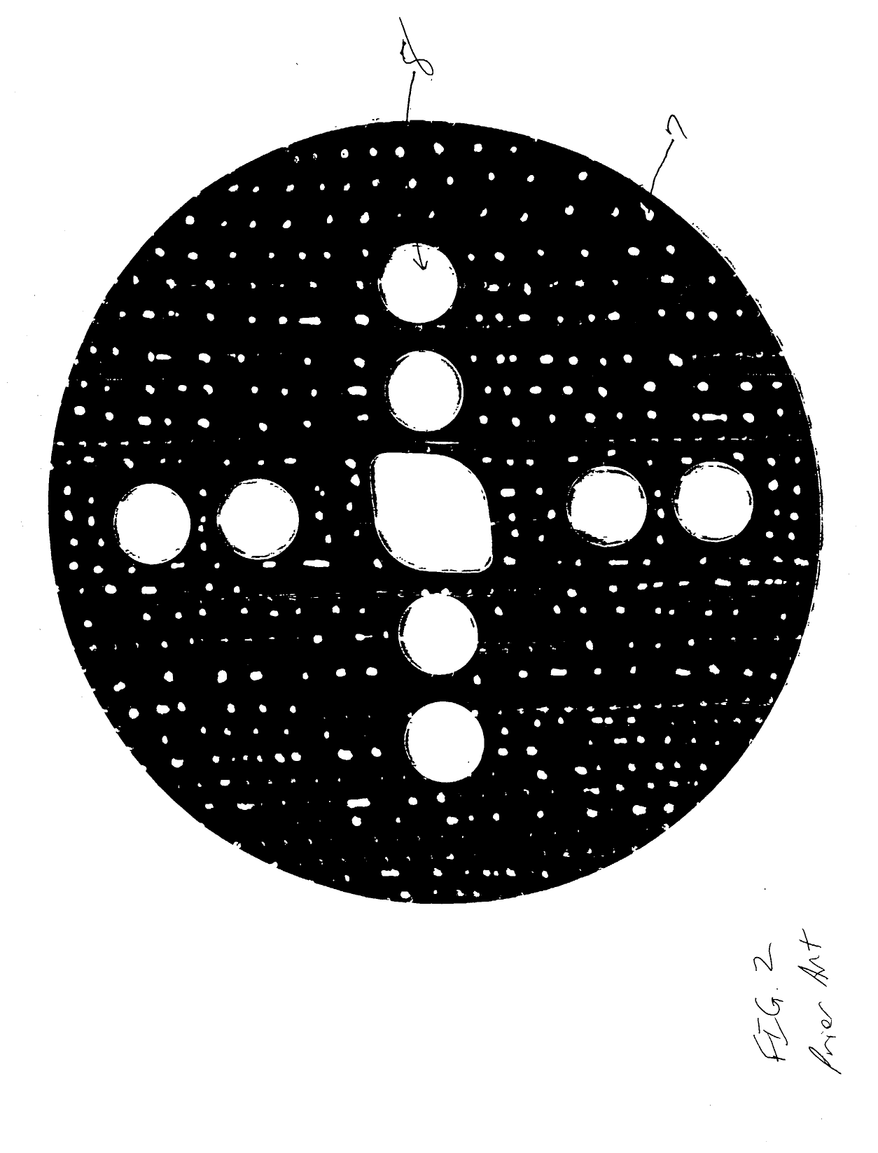

Referring again to the drawings, FIG. 2 is a top view of the pedestal film 5 (which is purchased from a company such as Applied Materials Inc.). The film 5 has perforations 7 that allow the film to more gently hold a wafer 3 under vacuum. Furthermore, the film 5 has holes 8 that allow the deionized water and vacuum to pass from the plate 4, through theholes 8 in film 5, and then onto the wafer 3.

There are tiny finger-like fibers located on the side of film 5 that contacts the wafer 3. These fibers give the film a velvet feel when touched. These fibers are prone to shedding. Furthermore, particles lodged in the film 5 are prone to attaching to the wafer 3. FIG. 3 is an example of a pedestal film contamination signature on a product wafer 3. The film particles and CMP residue will adversely affect the manufacturing yield.

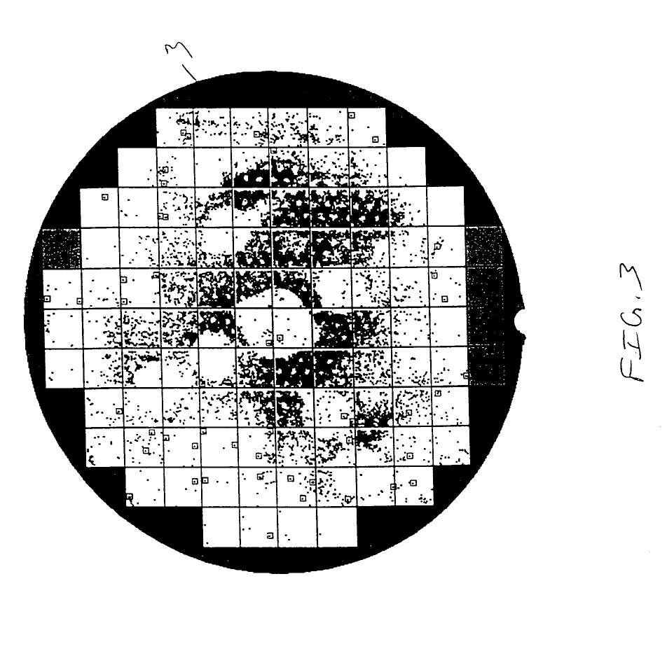

In accordance with the invention, the pedestal film is modified to minimize the contact between the film and the active wafer dies. FIG. 4 shows the top view of a modification to film 5 in accordance with the invention. It is within the scope of the invention to minimize the contact between the film 5 and the wafer 3 in any manner that allows the pedestal 2 to function properly. For example, the four pads 9 of film 5 located along the outside edge 10 of plate 4 provide good edge support to the wafer 3 while under vacuum. The inner piece 11 of film 5 provides good center support to the wafer 3. In this example, the vacuum is brought through the center of the film piece 11 when needed to hold the wafer 3 to the pedestal 2. The deionized water may also be brought through the center of the film piece 11 or may also be brought through the existing holes 8 on plate 4. (The edge 12 of wafer 3 is also indicated in this drawing.) It should be noted that this embodiment of the invention may be implemented with minimal cost and effort. Specifically, it is not necessary to perform any modifications to the pedestal 2 supplied by the manufacturer of the CMP machine. Furthermore, the film 5 is the same consumable product as the pedestal film usually purchased from the manufacturer of the CMP machine.

Referring again to the drawings, FIG. 5 shows another embodiment that is within the scope of the invention. As shown in FIG. 5, any shape 13 for the center piece of film will provide support to the center portion of wafer 3 while allowing deionized water and vacuum to flow through holes 8 from the tubings 6 (not shown). Furthermore, a circle of film 14 located along the outside edge 10 of plate 4 may provide the outer support for the wafer 3. Again, it should be noted that this embodiment of the invention may be implemented with minimal cost and effort. Specifically, there is no modification to the pedestal 2 supplied by the manufacturer of the CMP machine. Furthermore, the film 5 is the same consumable product as the pedestal film that is usually purchased from the manufacturer of the CMP machine. However, it is within the scope of this invention to use other materials. A silicon-based or other elastomer-based product may be used for any film area shown in FIGS. 4 and 5.

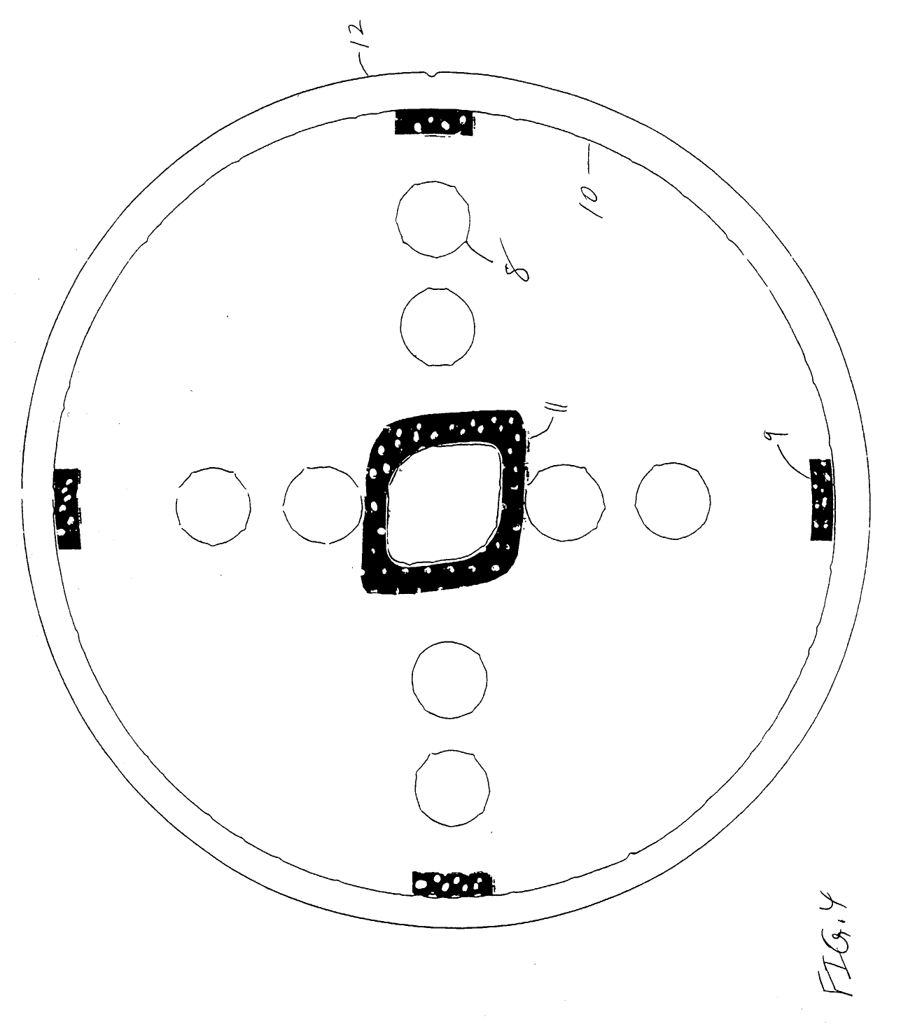

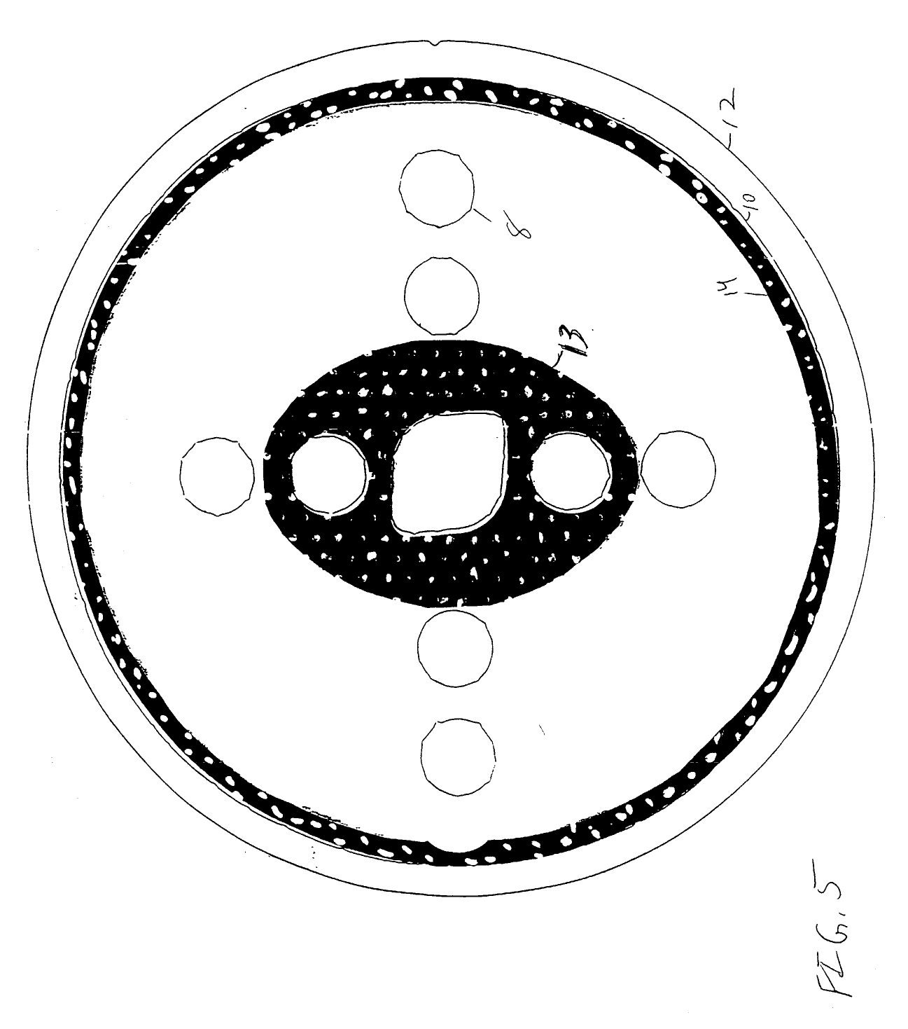

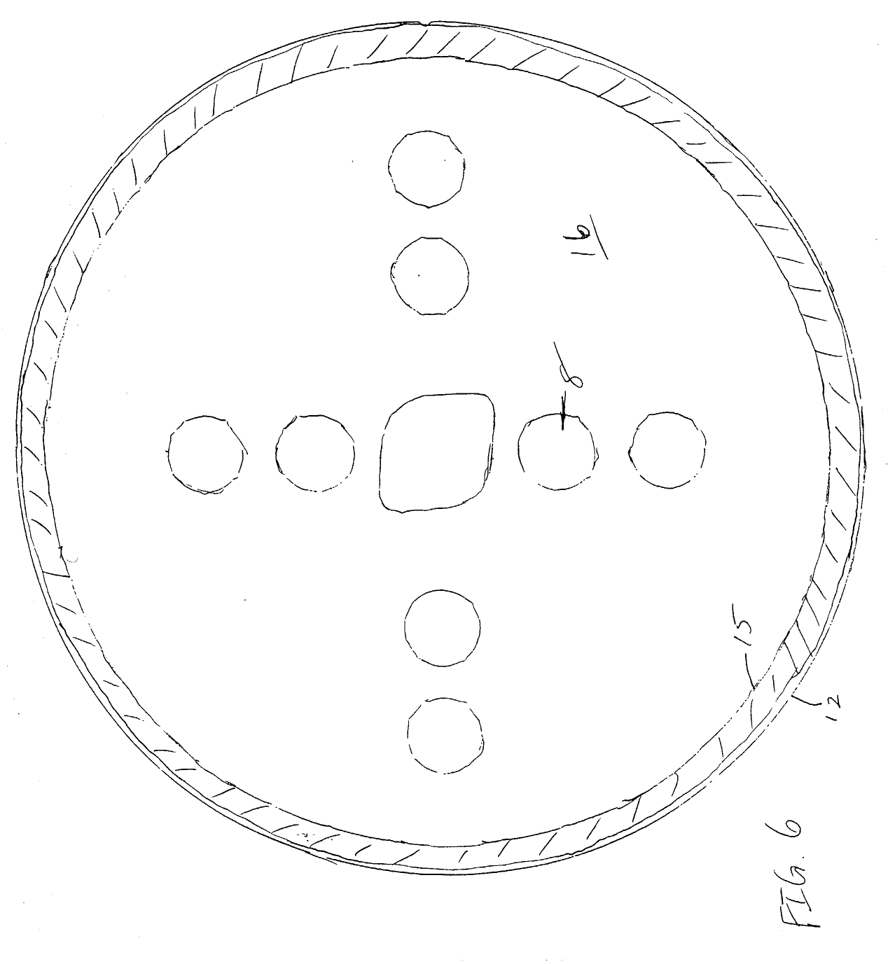

In the best mode application, shown in FIG. 6, the plate 16 is enlarged to match the circumference of the wafer 3. In addition, the edge-contact ring 15 is the interface between the pedestal 2 and the wafer 3 (instead of film 5). Moreover, in the best mode applicationthe edge-contact ring 15 does not touch any active die in the wafer 3.

The edge-contact ring 15 is used to provide support for the wafer 3. Furthermore, the edge-contact ring 15 facilitates a good quality seal when the vacuum is applied. In the best mode application, the edge-contact ring is 3-5 mm wide. When the edge-contact ring is less than 5 mm wide, it will contact the wafer only areas of the wafer that don't contain any full active die). However, the width of the edge-contact ring 15 may be anything less than the shortest distance between the edge 12 of wafer 3 and the closest corner of any active die.

Furthermore, in the best mode application the edge-contact ring 15 is the same material as the membrane used on the carrier. As an example, the edge-contact ring 15 is made from the semi-transparent silicon-based carrier membrane supplied by Applied Materials Inc. However. it is within the scope of the invention to use various materials for the edge-contact ring, such as other elastomer-based materials or the standard CMP pedestal film material.

Referring to the drawings, FIG. 7 shows the relationship between a wafer pedestal 2 and a wafer 3 in accordance with the best mode application. The tubings 6 providing deionized water and vacuum are unmodified from the prior art. As shown in FIG. 7, the plate portion 16 of the wafer pedestal 2 has the same circumference as the wafer 3. This modified plate 16 can be a plate that is manufactured separately; or the existing plate 4 provided by the CMP manufacturer may be modified in any one of numerous ways.

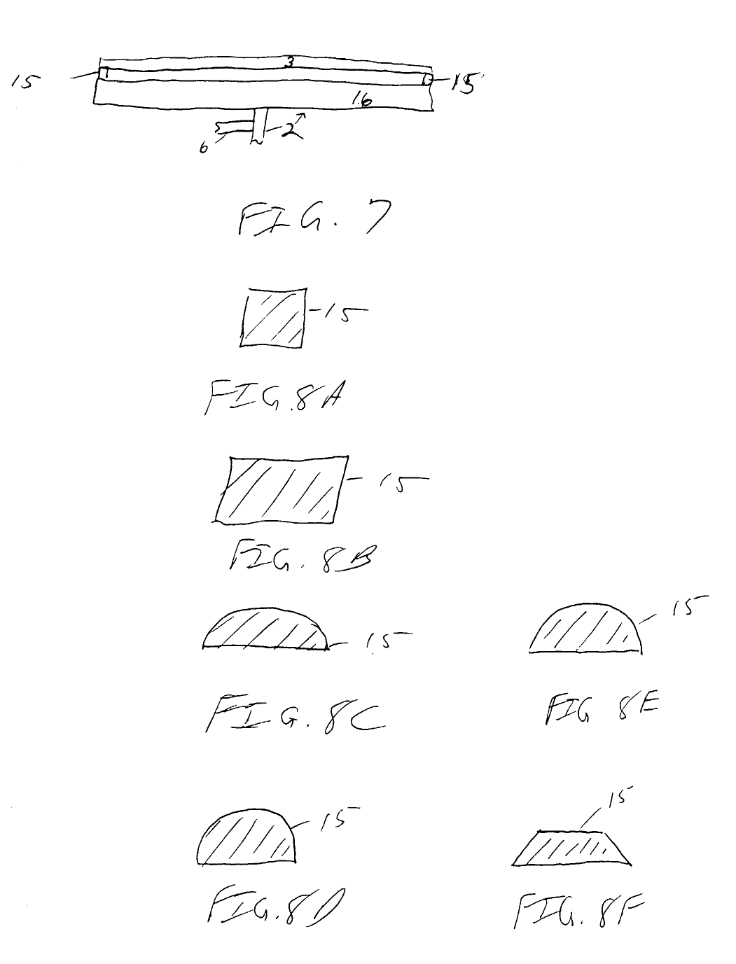

The edge-contact ring 15 touches the wafer 3 only at the outer edge of the wafer 3. It is within the scope of this invention to use any one of numerous cross-section shapes for the edge-contact ring 15. For example, the cross-section of edge-contact ring 15 may be square as shown in FIG. 8A, rectangular as shown in FIG. 8B, half oval as shown in FIG. 8C, D shaped as shown in FIG. 8D, half circle as shown in FIG. 8E, or trapezoidal as shown in FIG. 8F.

Various modifications to the invention as described above are within the scope of the claimed invention. As an example, the edge-contact ring may be any width. The edge-contact ring may even be wide enough to touch the active die areas of the wafer, if desired. In addition, it is within the scope of this invention to use plates 4 of any shape or made in any manner. Furthermore, this invention can be used with wafers of any shape or size. Moreover, this invention may be implemented on any surface on which wafers are placed or held during the manufacturing process.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A wafer pedestal comprising:
a plate;
pedestal film coupled to said plate, said pedestal film also coupled to a wafer in a manner where contact between said pedestal film and said wafer's active die is minimized.

2. The wafer pedestal of claim 1 wherein said plate and said pedestal film have holes for deionized water and a vacuum.

3. The wafer pedestal of claim 1 wherein said pedestal film is comprised of an elastomer-based material.

4. The wafer pedestal of claim 3 wherein said elastomer-based material is a silicon-based material.

5. A wafer pedestal comprising:
a plate having ports for providing deionized water and a vacuum;
an edge-contact ring coupled to said plate, said edge-contact ring also coupled to a wafer substantially in areas of said wafer not containing full active die.

6. The wafer pedestal of claim 5 wherein said edge-contact ring is comprised of a silicon-based material.

7. The wafer pedestal of claim 5 wherein said edge-contact ring is comprised of an elastomer-based material.

8. The wafer pedestal of claim 5 wherein the width of said edge-contact ring is 5 mm or less.

9. The wafer pedestal of claim 5 wherein said edge-contact ring has a cross-section that is shaped like a half oval.

10. The wafer pedestal of claim 5 wherein said edge-contact ring has a cross-section that is shaped like a “D”.

11. The wafer pedestal of claim 5 wherein said edge-contact ring has a cross-section that is shaped like a square.

12. The wafer pedestal of claim 5 wherein said edge-contact ring has a cross-section that is shaped like a rectangle.

13. The wafer pedestal of claim 5 wherein said edge-contact ring has a cross-section that is shaped like a half circle.

14. The wafer pedestal of claim 5 wherein said edge-contact ring has a cross-section that is shaped like a trapezoid.

15. A wafer pedestal comprising:
a plate;
an edge-contact ring coupled to said plate, said edge-contact ring also coupled to a wafer substantially in areas of said wafer not containing full active die.

16. The wafer pedestal of claim 15 wherein said plate hasports for providing deionized water and a vacuum.

17. The wafer pedestal of claim 15 wherein said edge-contact ring is comprised of a silicon-based material.

18. The wafer pedestal of claim 15 wherein said edge-contact ring is comprised of an elastomer-based material.

19. The wafer pedestal of claim 15 wherein the width of said edge-contact ring is 5 mm or less.

20. The wafer pedestal of claim 15 wherein said edge-contact ring has a cross-section that is shaped like a half oval.

21. The wafer pedestal of claim 15 wherein said edge-contact ring has a cross-section that is shaped like a “D”.

22. The wafer pedestal of claim 15 wherein said edge-contact ring has a cross-section that is shaped like a square.

23. The wafer pedestal of claim 15 wherein said edge-contact ring has a cross-section that is shaped like a rectangle.

24. The wafer pedestal of claim 15 wherein said edge-contact ring has a cross-section that is shaped like a half circle.

25. The wafer pedestal of claim 15 wherein said edge-contact ring has a cross-section that is shaped like a trapezoid.
